(19) United States
(12) Patent Application Publication
(10) Pub. No.: US 2017/0332499 A1
(43) Pub. Date: Nov. 16, 2017

(54) MODULE AND ELECTRONIC KEY USING MODULE

(71) Applicant: KABUSHIKI KAISHA TOKAI RIKA DENKI SEISAKUSHO, Aichi (JP)

(72) Inventors: Daisuke SENZAKI, Aichi (JP); Yuki KONO, Aichi (JP); Masayuki KAWAMURA, Aichi (JP); Hiroaki KOJIMA, Aichi (JP)

(21) Appl. No.: 15/531,932

(22) PCT Filed: Nov. 26, 2015
(86) PCT No.: PCT/JP2015/083205

§ 371 Date: May 31, 2017

(30) Foreign Application Priority Data
Dec. 2, 2014 (JP) 2014-243926

(51) Int. Cl. H05K 5/00; B60R 25/24; G07C 9/00; E05B 19/00

(52) U.S. Cl. CPC H05K 5/0086; B60R 25/24; H05K 5/0017; E05B 19/0082; G07C 9/00309; G07C 2009/00984; G07C 2009/00587

(57) ABSTRACT

A module includes a housing including a battery housing portion that houses a battery, an operation accepting unit including a first board including accepting means that accepts an operation and is arranged on the first board, the first board being attached to the housing, and a second board housed within the battery housing portion along with the battery. A control circuit electrically connected to the accepting means is arranged on the second board.

### TECHNICAL FIELD

The present invention relates to a module and an electronic key using the module.

### BACKGROUND ART

A portable device for an electronic key system is known, where a circuit board on which a communication circuit for wirelessly communicating with the exterior is mounted, a protective cover placed over one surface of the circuit board, and a plate-shaped battery holder that is placed over the other surface of the circuit board and that holds a battery, are housed within a case forming the outer form of a portable device main body (see Patent Document 1, for example).

### CITATION LIST

### Patent Document

Patent Document 1: Japanese Unexamined Patent Application Publication No. 2008-196194A

### SUMMARY OF INVENTION

### Technical Problem

With the portable device disclosed in Patent Document 1, the board pattern is required to be laid out and evaluated on the basis of the positions of switches, the high-frequency characteristics of wires, and the like each time the design of the portable device is changed. This is problematic in that doing so increases manufacturing costs.

An object of the present invention is to provide a module that can respond flexibly to design changes, and an electronic key using that module.

### Solution to Problem

A module according to an embodiment of the present invention includes: a housing including a battery housing portion that houses a battery; an operation accepting unit including a first board including accepting means that accepts an operation, and attached to the housing, the accepting means being arranged on the first board; and a second board housed within the battery housing portion along with the battery and including a control circuit electrically connected to the accepting means, the control circuit being arranged on the second board.

### Advantageous Effects of Invention

According to an embodiment of the present invention, a module that can respond flexibly to design changes, and an electronic key using that module, can be provided.

### BRIEF DESCRIPTION OF DRAWINGS

FIG. 1 is an exploded perspective view of an electronic key using a module according to an embodiment.

FIG. 2A is a top view of a housing of the electronic key according to the embodiment.

FIG. 2B is a cross-sectional view seen from the direction of arrows and taken along a line II(b)-II(b) in FIG. 2A.

FIG. 2C is a bottom view of the housing.

FIG. 2D is a side view of a left side surface from which a battery is inserted.

FIG. 2E is a cross-sectional view seen from the direction of arrows and taken along a line II(e)-II(e) in FIG. 2C.

FIG. 3A is a perspective view of the module according to the embodiment.

FIG. 3B is a left side view of the module.

FIG. 3C is a top view of the module.

FIG. 3D is a right side view of the module.

FIG. 3E is a front view of the module.

FIG. 3F is a perspective view of a control circuit unit and a battery terminal housed in a battery housing portion.

FIG. 3G is a cross-sectional view, taken along a line III(g)-III(g) in FIG. 3C, when a bottom surface of the housing is oriented upward.

FIG. 4A is a top view of a board of an interface unit in the module according to the embodiment.

FIG. 4B is an explanatory diagram illustrating a connection pattern between a switch SW1 and a switch SW2 in the module.

FIG. 5A is a perspective view illustrating a modified example of the electronic key that has a different design.

FIG. 5B is a perspective view illustrating a modified example of the electronic key that has a different design.

FIG. 5C is a perspective view illustrating a modified example of the electronic key that has a different design.

FIG. 5D is a perspective view illustrating a modified example of the electronic key that has a different design.

FIG. 5E is a perspective view illustrating a modified example of the electronic key that has a different design.

### DESCRIPTION OF EMBODIMENT

### Overview of Embodiment

A module according to an embodiment includes: a housing including a battery housing portion that houses a battery; an operation accepting unit including a first board including accepting means that accepts an operation, and attached to the housing, the accepting means being arranged on the first board; and a second board housed within the battery housing portion along with the battery and including a control circuit electrically connected to the accepting means, the control circuit being arranged on the second board.

### Embodiment

### Overall Configuration of Electronic Key 1

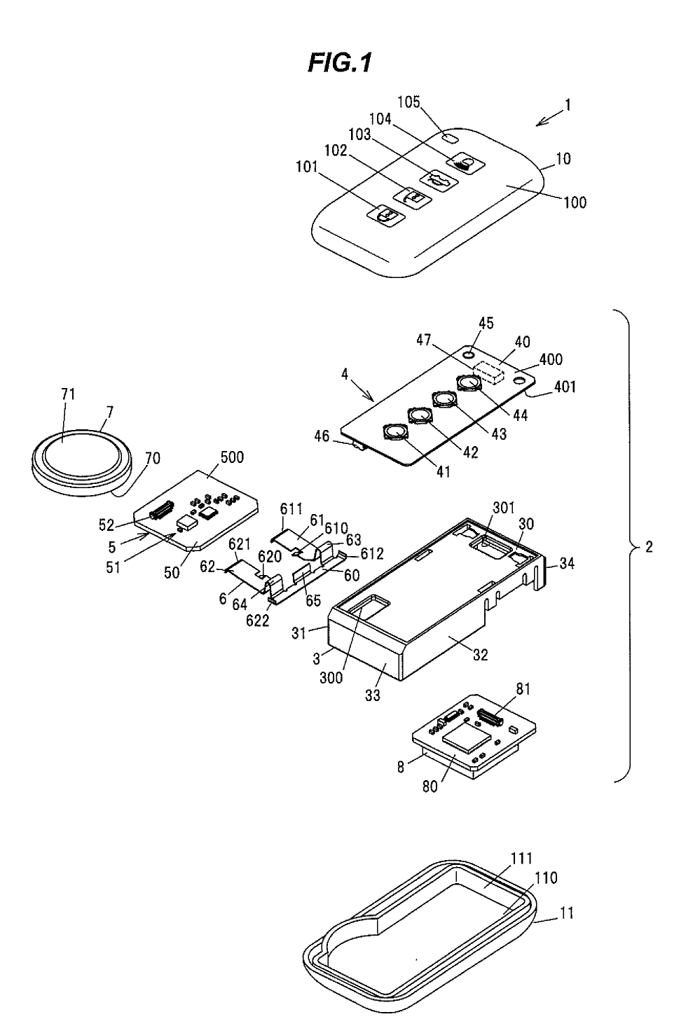

FIG. 1 is an exploded perspective view of an electronic key using a module according to an embodiment. In the drawings associated with the following embodiment, ratios between elements in the drawings may be different from the actual ratios.

This electronic key 1 is, for example, a portable device capable of wirelessly instructing a door of a vehicle to lock and unlock, an engine of the vehicle to start, and the like. The electronic key 1 according to the present embodiment verifies an ID through two-way communication with the vehicle. When the ID is successfully verified, the person carrying the electronic key 1 can carry out actions such as locking and unlocking a door of the vehicle.

As illustrated in FIG. 1, in the electronic key 1, a first button 101 to a fourth button 104 are arranged on an upper surface 100 of an upper case 10. The first button 101 to fourth button are configured to be capable of push operations, for example.

The upper case 10 is configured so as to be integrated with a lower case 11. As illustrated in FIG. 1, the electronic key 1 is configured so that a module 2 is housed within the upper case 10 and the lower case 11.

The module 2 includes a housing 3, an interface unit 4, and a board 50. The housing 3 includes a battery housing portion 37 that houses a battery 7. The interface unit 4, serving as an operation accepting unit, includes a board 40, serving as a first board, attached to the housing 3. Accepting means that accepts an operation is arranged on the board 40. The board 50, serving as a second board, is housed within the battery housing portion 37 along with the battery 7, and a control circuit 51 electrically connected to the accepting means is arranged on the board 50.

The module 2 further includes a battery terminal 6, housed within the battery housing portion 37 along with the battery 7 and the board 50, and electrically connected to the battery 7 and the control circuit 51.

The module 2 is not limited to the electronic key 1, and may be used in a portable device that can lock and unlock the front door of a house, remotely operate an electronic device, or the like.

### Configuration of Upper Case 10 and Lower Case 11

The upper case 10 and the lower case 11 are formed using a synthetic resin such as acrylonitrile butadiene styrene copolymer (ABS) resin or polycarbonate (PC) resin.

An operating light 105, for example, is disposed in the upper case 10 in addition to the first button 101 to the fourth button 104. The first button 101 to the fourth button 104 are configured to turn a first switch 41 to a fourth switch 44 of the module 2 (described later) on in response to a push operation that has been made. The operating light 105 outputs light from a light source 45 of the module 2 (described later) in response to the push operation. An operator recognizes that an operation has been accepted by the light outputted from the operating light 105.

As illustrated in FIG. 1, the lower case 11 has, in an inside base surface 110, a housing portion 111 having a shape corresponding to the module 2. The housing portion 111 houses the module 2 and holds the module 2 along with the upper case 10. The housing portion 111 includes a recess, formed therein, corresponding to the shape of the battery 7 incorporated into the module 2. The battery 7 is a button-type battery having a disk shape. An upper portion of the battery 7 corresponds to a positive electrode 70, and a lower portion of the battery 7 that has a smaller radius than that of the positive electrode 70 corresponds to an negative electrode 71.

The battery 7 is not limited to a button-type battery, and as a modified example, the battery 7 may be a secondary battery. In the case of a secondary battery, for example, an extended function unit 8 (described later) that enables the secondary battery to be charged in a non-contact manner, or an extended function unit 8 that enables the secondary battery to be charged via a cable, is added to the electronic key 1.

The electronic key 1 may be configured to contain a physical key for situations where the module 2 has become unable to communicate with the vehicle. This physical key is disposed between the housing portion 111 and the upper and lower cases 10 and 11, for example.

### Overall Configuration of Module 2

The module 2 includes the housing 3, the interface unit 4, a control circuit unit 5, the battery terminal 6, the battery 7, and the extended function unit 8. The interface unit 4, the control circuit unit 5, the battery terminal 6, the battery 7, and the extended function unit 8 are housed within the housing 3 in an integrated manner.

In the case where the extended function unit 8 is not incorporated into the module 2, the electronic key 1 can lock and unlock a door by operating a button, for example. However, in the case where the extended function unit 8 is incorporated into the module 2, the functions of the electronic key 1 are extended, such that the electronic key 1 can lock or unlock a door by the operator approaching the vehicle or the operator touching the door, for example.

### Configuration of Housing 3

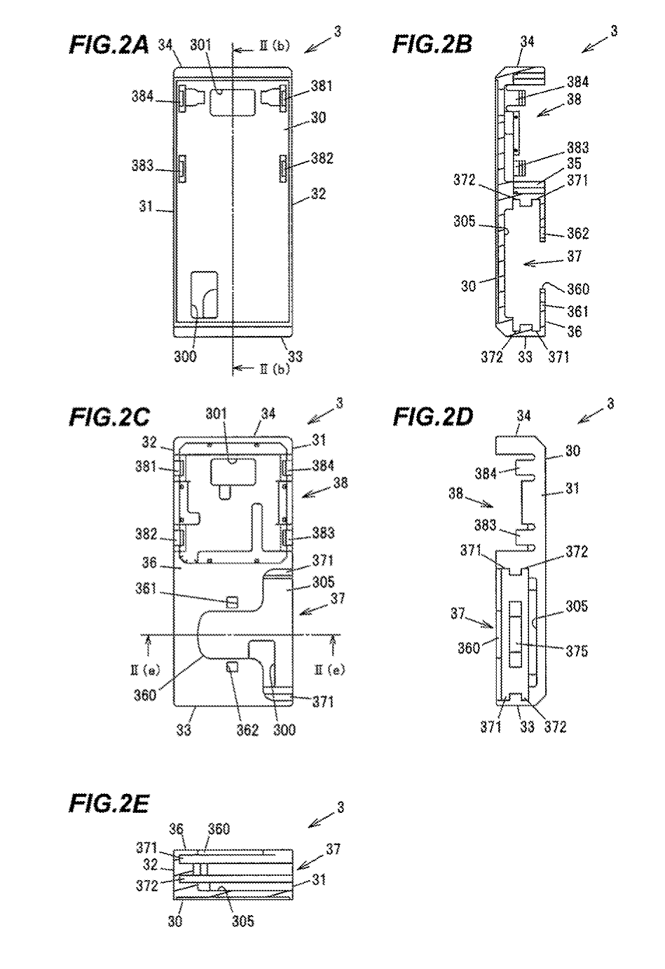

FIG. 2A is a top view of the housing of the electronic key according to the embodiment, FIG. 2B is a cross-sectional view seen from the direction of arrows and taken along a line II(b)-II(b) in FIG. 2A, FIG. 2C is a bottom view of the housing, FIG. 2D is a side view of a left side surface from which the battery is inserted, and FIG. 2E is a cross-sectional view seen from the direction of arrows and taken along a line II(e)-II(e) in FIG. 2C.

The housing 3 is formed using a synthetic resin such as ABS resin or PC resin, for example. As illustrated in FIGS. 1 and 2A, the interface unit 4 is arranged on an arrangement surface 30 of the housing 3 formed as a rectangular recess in the upper surface of the housing 3.

The housing 3 has a board housing portion 38 serving as a housing portion that houses the extended function unit 8, which has a function different from the functions of the first switch 41 to fourth switch 44.

Specifically, as illustrated in FIG. 2B, the battery housing portion 37 is provided on a front surface 33 side of the housing 3, and the board housing portion 38 is provided on a rear surface 34 side of the housing 3, with a wall 35 of the housing 3 serving as a boundary between these portions.

The housing 3 also includes a connector opening 300 serving as a first opening opened in the battery housing portion 37, and a connector opening 301 serving as a second opening opened in the board housing portion 38.

The connector opening 300 and the connector opening 301 are rectangular in shape, and are provided in the arrangement surface 30. The connector opening 300 and the connector opening 301 are, for example, arranged such that long-side directions thereof are at 90° angles relative to each other.

As illustrated in FIGS. 2C and 2E, the battery housing portion 37 is open on a left side surface 31. Terminal holding grooves 371 serving as first guide grooves that guide the insertion of the battery terminal 6 and board holding grooves 372 serving as second guide grooves that guide the insertion of the board 50 are provided on opposing side surfaces. These opposing side surfaces are side surfaces of the wall 35 and the front surface 33 and located on the battery housing portion 37 sides of the wall 35 and the front surface 33.

Additionally, in the battery housing portion 37, a recess part 305 that houses a connector 52 and the like arranged on the board 50 is provided on the arrangement surface 30 side, and a recess part 375 conforming to the outer shape of the battery 7 is provided on a right side surface 32 side.

A removal recess part 360 recessed in a direction in which the battery 7 is removed is formed in a bottom surface 36 of the battery housing portion 37 so that the battery 7 housed within the battery housing portion 37 can be removed easily. As illustrated in FIG. 2C, a rectangular cutout hole 361 and a rectangular cutout hole 362 are formed on both sides of the removal recess part 360. The cutout hole 361 and the cutout hole 362 are provided so that a projecting portion 610 and a projecting portion 620 of the battery terminal 6 (described later) are fitted into the cutout hole 361 and the cutout hole 362 when the battery 7 is housed within the battery housing portion 37. The projecting portion 610 and the projecting portion 620 being fitted into the cutout hole 361 and the cutout hole 362 prevents the battery terminal 6 from being pulled out from the battery housing portion 37.

The above-described connector opening 300 is provided in the battery housing portion 37. The connector 52 of the board 50 of the control circuit unit 5 (described later) is connected to a connector 46 of the interface unit 4 via the connector opening 300.

A board 80 of the extended function unit 8 is housed within the board housing portion 38. A first pawl portion 381 to a fourth pawl portion 384 are provided, clockwise in the plane in FIG. 2A, in the board housing portion 38. The first pawl portion 381 and the second pawl portion 382 are arranged in a row, and the third pawl portion 383 and the fourth pawl portion 384 are arranged in a row. The first pawl portion 381 opposes the fourth pawl portion 384, and the second pawl portion 382 opposes the third pawl portion 383. Side surface parts of the board 80 are fitted with the first pawl portion 381 to fourth pawl portion 384, and the board 80 is held as a result.

The above-described connector opening 301 is provided in the board housing portion 38. A connector 81 of the board 80 is connected to a connector 47 of the interface unit 4 via the connector opening 301.

### Configuration of Interface Unit 4

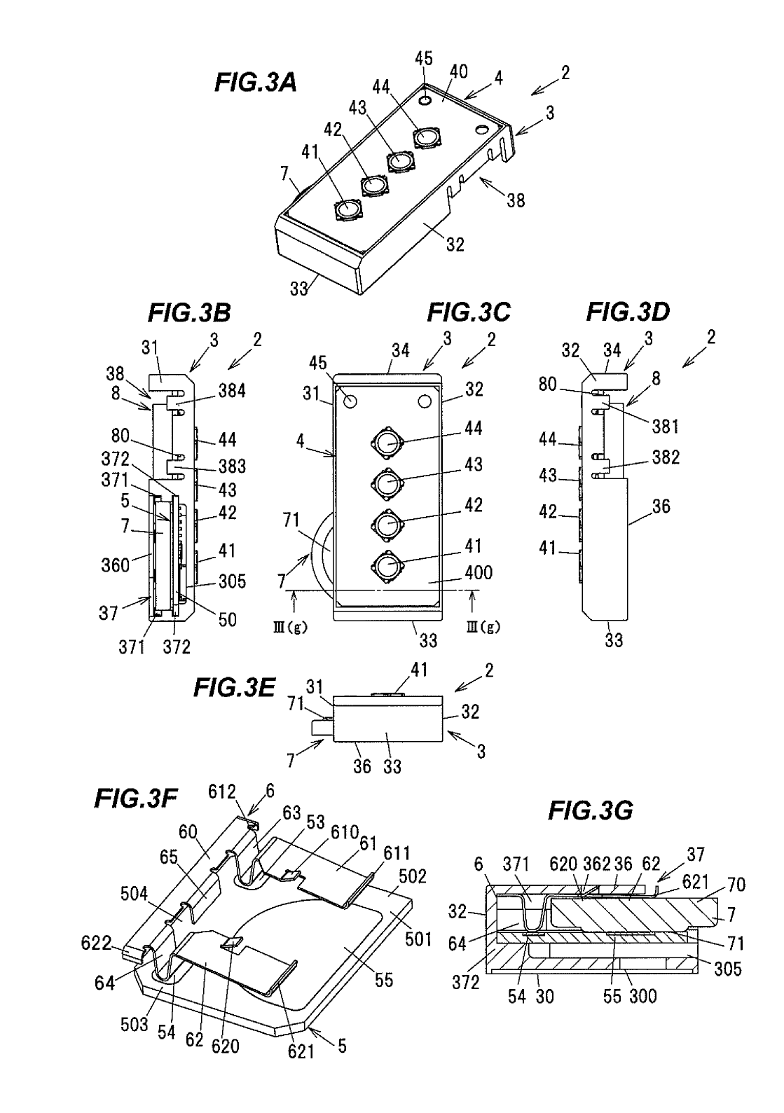

FIG. 3A is a perspective view of the module according to the embodiment, FIG. 3B is a left side view of the module, FIG. 3C is a top view of the module, FIG. 3D is a right side view of the module, FIG. 3E is a front view of the module, FIG. 3F is a perspective view of the control circuit unit and the battery terminal housed in the battery housing portion, and FIG. 3G is a cross-sectional view, taken along a line III(g)-III(g) in FIG. 3C, when the bottom surface of the housing is oriented upward.

The interface unit 4 is constituted of, for example, the accepting means that accepts operations from an operator, indicating means that indicates the acceptance of an operation, and the like. Specifically, the interface unit 4 is configured including a light source, a switch, a touch sensor, a display, a microphone, a speaker, a camera, a photovoltaic panel, or the like, for example. The accepting means according to the present embodiment is the first switch 41 to the fourth switch 44, for example.

The interface unit 4 further includes the light source 45 on a front surface 400 of the board 40, for example. Additionally, in the interface unit 4, the connector 46 and the connector 47 are provided on a back surface 401 side of the board 40.

As illustrated in FIGS. 3A and 3C, the board 40 of the interface unit 4 is, for example, a printed wiring board having a long, narrow, rectangular shape. As illustrated in FIGS. 3A to 3E, the board 40 has a shape corresponding to the arrangement surface 30 of the housing 3.

The first switch 41 to the fourth switch 44 are, for example, surface-mounted microswitches. The first switch 41 to the fourth switch 44 are arranged in a row so as to correspond to the arrangement of the first button 101 to the fourth button 104 in the upper case 10.

The first switch 41 turns on in response to a push operation made on the first button 101, and this locks a door of the vehicle, for example. The second switch 42 turns on in response to a push operation made on the second button 102, and this unlocks the door of the vehicle, for example. The third switch 43 turns on in response to a push operation made on the third button 103, and this opens the trunk of the vehicle, for example. The fourth switch 44 turns on in response to a push operation made on the fourth button 104, and this causes the vehicle to sound an alarm, for example.

Switch signals outputted from the first switch 41 to the fourth switch 44 are outputted to the control circuit unit 5 via the connector 46, for example. The control circuit unit 5 generates a transmission signal to be transmitted to the vehicle in response to the inputted switch signal, and wirelessly outputs the transmission signal to the vehicle.

The light source 45 is constituted of a light-emitting element, for example. The light source 45 is configured such that current is supplied from the battery 7 to the light source 45 via the connector 52 and the connector 46 when the first switch 41 to the fourth switch 44 turn on, and the light source 45 emits light.

A board pattern 48 formed on the board 40 of the interface unit 4 will be described next.

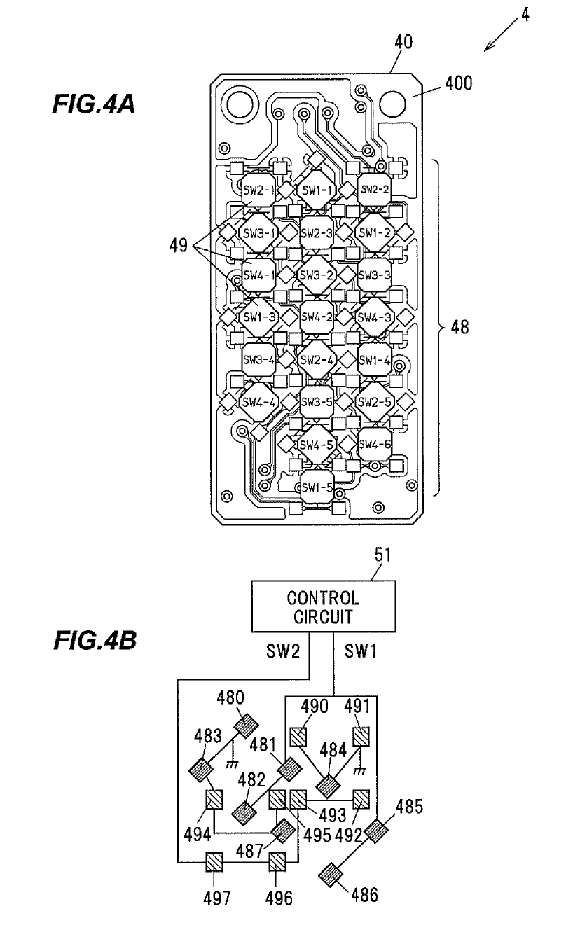

FIG. 4A is a top view of the board of the interface unit in the module according to the embodiment, and FIG. 4B is an explanatory diagram illustrating a connection pattern between a switch SW1 and a switch SW2 in the module.

As illustrated in FIG. 4A, the board 40 has the board pattern 48, in which a plurality of switches SW can be arranged. A maximum of four switches SW1 to SW4 can be arranged in the board pattern 48, for example.

As illustrated in FIG. 4A, not only can the four switches SW1 to SW4 be arranged in the board pattern 48, but the switches SW1 to SW4 can also be arranged in various arrangement positions 49. For example, the switch SW1 can be arranged at five locations indicated by SW1-1 to SW1-5, the switch SW2 can be arranged at five locations indicated by SW2-1 to SW2-5, the switch SW3 can be arranged at five locations indicated by SW3-1 to SW3-5, and the switch SW4 can be arranged at six locations indicated by SW4-1 to SW4-6.

Specifically, with the board pattern 48, the switches can be arranged in the arrangement positions 49 without changing the arrangements of pads to which wires and the switches are connected. In other words, the switch SW1 is arranged at one of the arrangement positions 49 indicated by SW1-1 to SW1-5 in FIG. 4A. The switch SW2 is arranged at one of the arrangement positions 49 indicated by SW2-1 to SW2-5 in FIG. 4A. The switch SW3 is arranged at one of the arrangement positions 49 indicated by SW3-1 to SW3-5 in FIG. 4A. The switch SW4 is arranged at one of the arrangement positions 49 indicated by SW4-1 to SW4-6 in FIG. 4A.

Next, an example of the electrical connections for the arrangement positions 49 of SW1-1, SW1-2, SW2-2, and SW2-3, illustrated in FIG. 4B, will be described.

SW1-1 has a pad 480 to a pad 483. SW1-2 has a pad 484 to a pad 487. SW2-2 has a pad 490 to a pad 493. SW2-3 has a pad 484 to a pad 487.

The pad 480, the pad 483, the pad 487, the pad 494, and the pad 495 are electrically connected to each other and are also grounded. The pad 481 and the pad 482 are electrically connected to each other and are also electrically connected to the control circuit 51. The pad 485 and the pad 486 are electrically connected to each other and are also electrically connected to the control circuit 51.

The pad 484, the pad 490, and the pad 491 are electrically connected to each other and are also grounded. The pad 492, the pad 493, the pad 496, and the pad 497 are electrically connected to each other and are also electrically connected to the control circuit 51.

Because SW1-1, SW1-2, SW2-2, and SW2-3 have the pads connected as described above, the switch SW1 can be arranged as SW1-1 or SW1-2, and the switch SW2 can be arranged as SW2-2 or SW2-3, for example.

Note that in the board pattern 48, it is sufficient for at least one of the four switches to be arranged. Additionally, the control circuit 51 detects SW1 to SW4, and thus the switches may be arranged at any of the arrangement positions 49 for SW1 to SW4, regardless of the order in which the buttons are arranged in the upper case 10.

Note also that the board pattern 48 is not limited to a configuration in which switches are arranged for pads. For example, the configuration may be such that a push operation made on a button brings a conductive lower portion of the button into contact with two terminals arranged on the board 40 such that the two terminals conduct.

### Configuration of Control Circuit Unit 5

As illustrated in FIG. 1, the control circuit unit 5 includes the board 50, a control circuit 51, the connector 52, a first positive terminal 53 and a second positive terminal 54 serving as a first conductive portion, and a negative terminal 55 serving as a second conductive portion.

The board 50 is a rectangular printed wiring substrate, for example. The control circuit 51 and the connector 52 are arranged on an arrangement surface 500 of the board 50. The first positive terminal 53, the second positive terminal 54, and the negative terminal 55 are arranged on a terminal surface 501 corresponding to the back surface of the arrangement surface 500 of the board 50.

The control circuit 51 is constituted of a controller including a central processing unit (CPU) and the like, a communicator that wirelessly communicates with the vehicle, and the like, for example. The control circuit 51 is electrically connected to the first positive terminal 53, the second positive terminal 54, and the negative terminal 55, and is furthermore electrically connected to the connector 52.

The first positive terminal 53, the second positive terminal 54, and the negative terminal 55 are formed in plate shapes from an electrically conductive metal material such as copper or an alloy material containing such a metal material, for example. Note that a configuration is possible in which only one of the first positive terminal 53 and the second positive terminal 54 is provided on the control circuit unit 5, or a terminal obtained by forming the first positive terminal 53 and the second positive terminal 54 as a continuous entity may be provided.

### Configuration of Battery Terminal 6

The battery terminal 6 is formed from an electrically conductive metal material such as copper or an alloy material containing such a metal material, for example.

As illustrated in FIG. 3F, the battery terminal 6 includes: a base portion 60 that is longer in a direction intersecting with an insertion direction of the battery 7; a first terminal 61 and a second terminal 62, extending from both ends of the base portion 60 in the direction opposite from the insertion direction, and making contact with one of the electrodes of the inserted battery 7; and a curved portion 63 and a curved portion 64, provided on the first terminal 61 and the second terminal 62, respectively, and curving toward the board 50, the curved portion 63 and the curved portion 64 making contact with the first positive terminal 53 and the second positive terminal 54 of the board 50.

The base portion 60 includes a support portion 65, a guide portion 612, and a guide portion 622. The support portion 65 is provided in the center of the base portion 60, on the side surface thereof on which the first terminal 61 and the second terminal 62 are located. The support portion 65 is formed by bending a part projecting from the side surface in the same direction as the curved portion 63 and the curved portion 64. The support portion 65 suppresses deformation in the base portion 60 caused by the battery 7 being inserted or the like, for example.

As illustrated in FIG. 3F, the guide portion 612 is formed by bending an end part of the base portion 60 on the first terminal 61 side thereof in the same direction as the curved portion 63. The guide portion 612 is inserted into the terminal holding groove 371 on the wall 35 side of the battery housing portion 37.

As illustrated in FIG. 3F, the guide portion 622 is formed by bending an end part of the base portion 60 on the second terminal 62 side thereof in the same direction as the curved portion 64. The guide portion 622 is inserted into the terminal holding groove 371 on the front surface 33 side of the battery housing portion 37.

In the first terminal 61, the curved portion 63 is provided on the base portion 60 side, and a distal end portion 611 is provided on the opposite side therefrom. Additionally, the projecting portion 610 that projects in a direction opposite from the direction of contact with the battery 7 is provided in the first terminal 61.

The curved portion 63 is formed by bending the first terminal 61 on the base portion 60 side in a substantially elliptical shape. As illustrated in FIG. 3G, an elastic force caused by deformation is produced when the control circuit unit 5, the battery terminal 6, and the battery 7 are housed in the battery housing portion 37, and as a result the curved portion 63 makes contact with the first positive terminal 53 of the board 50. This elastic force ensures contact pressure between the curved portion 63 and the first positive terminal 53.

As will be described later, the first terminal 61 makes contact with the positive electrode 70 of the inserted battery 7, and thus the first positive terminal 53 is electrically connected to the positive electrode 70 via the battery terminal 6.

The projecting portion 610 is formed by bending a part of the first terminal 61, on the inner side of the shorter direction thereof, with the part of the projecting portion 610 located on the curved portion 63 side serving as a base point. To be more specific, the projecting portion 610 is formed by bending a part of the projecting portion 60 on the side opposite from the curved portion 63, or in other words, the distal end portion 611 side, toward the bottom surface 36 of the housing 3.

The distal end portion 611 is formed by bending a distal end of the first terminal 61 in the same direction as the projecting portion 610. The distal end portion 611 is provided to make it easy to insert the battery 7.

In the second terminal 62, the curved portion 64 is provided on the base portion 60 side, and a distal end portion 621 is provided on the opposite side therefrom. Additionally, the projecting portion 620 that projects in the direction opposite from the direction of contact with the battery 7 is provided in the second terminal 62.

The curved portion 64 is formed by bending the second terminal 62 on the base portion 60 side in a substantially elliptical shape. As illustrated in FIG. 3G, an elastic force caused by deformation is produced when the control circuit unit 5, the battery terminal 6, and the battery 7 are housed in the battery housing portion 37, and as a result the curved portion 64 makes contact with the second positive terminal 54 of the board 50. This elastic force ensures contact pressure between the curved portion 64 and the second positive terminal 54.

As will be described later, the second terminal 62 makes contact with the positive electrode 70 of the inserted battery 7, and thus the second positive terminal 54 is electrically connected to the positive electrode 70 via the battery terminal 6.

The projecting portion 620 is formed by bending a part of the second terminal 62, on the inner side of the shorter direction thereof, with the part of the projecting portion 620 located on the curved portion 64 side serving as a base point. To be more specific, the projecting portion 620 is formed by bending a part of the projecting portion 620 on the side opposite from the curved portion 64, or in other words, the distal end portion 621 side, toward the bottom surface 36 of the housing 3.

The distal end portion 621 is formed by bending a distal end of the second terminal 62 in the same direction as the projecting portion 620. Like the distal end portion 611, the distal end portion 621 is provided to make it easy to insert the battery 7.

The incorporation of the control circuit unit 5, the battery terminal 6, and the battery 7 will be described next.

### Incorporation of Battery Terminal 6 and the Like

### INCORPORATION OF BATTERY TERMINAL 6

First, the guide portion 612 and the guide portion 622 of the battery terminal 6 are fitted into the terminal holding grooves 371 of the battery housing portion 37 in the housing 3, after which the battery terminal 6 is inserted into the battery housing portion 37 so that the battery terminal 6 is incorporated into the battery housing portion 37.

Specifically, when the guide portion 612 and the guide portion 622 are inserted into the terminal holding grooves 371, the groove spacing is smaller than the spacing between the guide portion 612 and the guide portion 622, and thus, the guide portion 612 and the guide portion 622 deform inward. This deformation ensures that the guide portion 612 and the guide portion 622 remain in contact with the terminal holding grooves 371.

### INCORPORATION OF CONTROL CIRCUIT UNIT 5

Next, an end portion 502 and an end portion 503 of the board 50 of the control circuit unit 5 are fitted into the board holding grooves 372 of the battery housing portion 37 so that the control circuit unit 5 is incorporated into the battery housing portion 37.

### INCORPORATION OF BATTERY 7

Next, the battery 7 is inserted between the board 50 and the first and second terminals 61 and 62 so that the battery 7 is incorporated into the battery housing portion 37.

Specifically, when the battery 7 is inserted into the battery housing portion 37, first, the periphery of the battery 7 makes contact with the distal end portion 611 of the first terminal 61 and the distal end portion 621 of the second terminal 62. The battery 7 pushes the first terminal 61 and the second terminal 62 upward via the distal end portion 611 and the distal end portion 621. When the battery 7 is inserted further into the battery housing portion 37 and the battery 7 is housed within the battery housing portion 37, the first terminal 61 and the second terminal 62 are pushed further upward. As a result, the projecting portion 610 fits with the cutout hole 361 and the projecting portion 620 fits with the cutout hole 362, as illustrated in FIG. 3G.

Additionally, as illustrated in FIG. 3G, when the battery 7 is housed within the battery housing portion 37, the positive electrode 70 of the battery 7 makes contact with the first terminal 61 and the second terminal 62, and the negative electrode 71 of the battery 7 makes contact with the negative terminal 55 of the board 50. The first terminal 61 and the second terminal 62 produce an elastic force when the battery 7 is sandwiched between the board 50 and the first and second terminals 61 and 62. This elastic force maintains contact between the positive electrode 70 and the first and second terminals 61 and 62, and maintains contact between the negative electrode 71 and the negative terminal 55.

As a result of this incorporation, the positive electrode 70 of the battery 7 is electrically connected to the first positive terminal 53 and the second positive terminal 54 of the board 50 via the battery terminal 6, the negative electrode 71 of the battery 7 is electrically connected to the negative terminal 55 of the board 50, and the battery 7 is electrically connected to the control circuit 51.

MODIFIED EXAMPLES

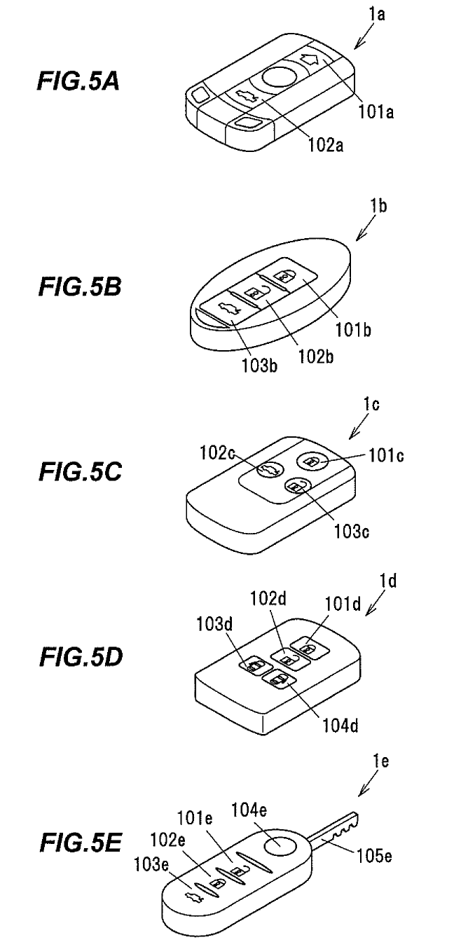

FIGS. 5A to 5E are perspective views illustrating modified examples of the electronic key that have different designs.

An electronic key 1a illustrated in FIG. 5A has a button 101a and a button 102a arranged at a distance from each other, for example. This electronic key 1a is configured such that in the board pattern 48, a switch corresponding to the button 101a is arranged at SW1-1 and a switch corresponding to the button 102a is arranged at SW4-5, for example.

An electronic key 1b illustrated in FIG. 5B has a button 101b to a button 103b arranged in a row, for example. This electronic key 1b is configured such that in the board pattern 48, a switch corresponding to the button 101b is arranged at SW1-1, a switch corresponding to the button 102b is arranged at SW3-2, and a switch corresponding to the button 103b is arranged at SW2-4, for example.

An electronic key 1c illustrated in FIG. 5C has a button 101c to a button 103c arranged at respective points of a triangle, for example. This electronic key 1c is configured such that in the board pattern 48, a switch corresponding to the button 101c is arranged at SW1-1, a switch corresponding to the button 102c is arranged at SW4-1, and a switch corresponding to the button 103c is arranged at SW3-3, for example.

An electronic key 1d illustrated in FIG. 5D has a button 101d to a button 104d, for example. The button 101d and the button 102d are arranged so as to correspond to a front-rear direction of a vehicle. The button 103d and the button 104d are buttons for opening and closing sliding doors on respective sides of the vehicle, for example, and are arranged adjacent to each other so as to correspond to a left-right direction of the vehicle.

This electronic key 1d is configured such that in the board pattern 48, a switch corresponding to the button 101d is arranged at SW2-3, a switch corresponding to the button 102d is arranged at SW4-2, a switch corresponding to the button 103d is arranged at SW3-4, and a switch corresponding to the button 104d is arranged at SW1-4, for example.

An electronic key 1e illustrated in FIG. 5E has a button 101e to a button 103e, a push-button 104e, and a physical key 105e. Switches for the button 101e to the button 101e are arranged in the arrangement positions 49 in the same manner as the electronic key 1b described above, for example. The physical key 105e swings out from a side surface in response to the push-button 104e being pressed, and is arranged between the module 2 and a case of the electronic key 1e, for example. In this manner, the module 2 can flexibly respond to electronic keys having different designs.

### Effects of Embodiment

The module 2 according to the present embodiment can flexibly respond to design changes. Specifically, the interface unit 4 in which the first switch 41 to the fourth switch 44 are provided and the control circuit unit 5 in which the control circuit 51 is provided are formed on separate boards, and thus the module 2 can respond to electronic keys having different designs by changing the positions of the switches in the interface unit 4 or the like. Accordingly, the module 2 can respond to design changes more flexibly than in a case where the accepting means that accepts operations and the control circuit are provided on the same board.

In the module 2, the interface unit 4 and the control circuit unit 5 are separate units, and the switch arrangement is flexible. This eliminates the needs for changing the layout for each electronic key having a different design. Thus, according to the module 2, it is not necessary to change the layout of the board pattern 48 to accommodate changes in the positions of switches, changes in the positions of wires based on high-frequency characteristics, and the like. This makes it possible for the module 2 to respond to multiple designs using a single configuration, which in turn makes it possible to reduce manufacturing costs.

The module 2 can suppress conduction problems between the battery 7 and the control circuit 51, and can improve the ease of assembly. Specifically, according to the module 2, the battery terminal 6, the control circuit unit 5, and the battery 7 are housed within the battery housing portion 37 of the housing 3 of the module 2. This ensures conduction between the battery 7 and the control circuit 51 of the control circuit unit 5, and this in turn makes it possible to suppress conduction problems between the battery 7 and the control circuit 51 and improve the ease of assembly as compared to a case where the terminals are fixed to the board using solder or the like.

The module 2 does not require a member that sandwiches the board from both sides in order to ensure contact pressure between the battery and the terminals provided on the board. The module 2 thus has a low number of components and can be manufactured at a low cost.

According to the module 2, the battery 7 can be attached to the module 2 by housing the battery terminal 6 and the control circuit unit 5 within the battery housing portion 37, and thus the assembly is easier than in a case where the terminals are attached to the board.

According to the module 2, the extended function unit 8 can be replaced, and thus, the electronic key 1 can be applied flexibly in electronic keys having different specifications.

Although several embodiments of the present invention and modified examples thereof have been described above, these embodiments and modified examples are merely examples, and the invention according to claims is not intended to be limited thereto. Such novel embodiments and modified examples can be implemented in various other forms, and various omissions, substitutions, changes, and the like can be made without departing from the spirit and scope of the present invention. In addition, all combinations of the features described in these embodiments and modified examples are not necessary to solve the problem. Furthermore, these embodiments and modified examples are included within the spirit and scope of the invention and also within the scope of the invention described in the claims and equivalents thereof.

### INDUSTRIAL APPLICABILITY

The present invention can be applied in electronic keys required to flexibly respond to design changes.

### REFERENCE SIGNS LIST

1, 1a to 1e ELECTRONIC KEY

2 MODULE

3 HOUSING

4 INTERFACE UNIT

6 BATTERY TERMINAL

7 BATTERY

8 EXTENDED FUNCTION UNIT

37 BATTERY HOUSING PORTION

40 BOARD

50 BOARD

51 CONTROL CIRCUIT

111 HOUSING PORTION

300 CONNECTOR OPENING

301 CONNECTOR OPENING

1. A module, comprising:
a housing comprising a battery housing portion that houses a battery;
an operation accepting unit comprising a first board comprising accepting means that accepts an operation and is arranged on the first board, the first board being attached to the housing; and
a second board housed within the battery housing portion along with the battery,
wherein a control circuit electrically connected to the accepting means is arranged on the second board.

2. The module according to claim 1, wherein the housing further comprises a first opening opened in the battery housing portion, and
wherein the accepting means and the control circuit are electrically connected via the first opening.

3. The module according to claim 1, further comprising a battery terminal housed within the battery housing portion along with the battery,
wherein the second board and electrically connected to the battery and the control circuit.

4. The module according to claim 1, wherein the housing further comprises a housing portion that houses an extended function unit having a different function from a function of the accepting means, and
wherein the extended function unit and the control circuit are electrically connected via the first board.

5. The module according to claim 4, wherein the housing further comprises a second opening opened in the housing portion, and
wherein the first board and the extended function unit are connected via the second opening.

6. An electronic key using the module according to claim 1.

7. The module according to claim 1, wherein the first board and the second board are separated by the housing.

8. An electronic key using the module according to claim 7.
